(19) United States
(12) Patent Application Publication
(10) Pub. No.: US 2026/0206619 A1
(43) Pub. Date: Jul. 16, 2026

(54) SUBSTRATE ARCHITECTURE, STACKED SUBSTRATE ARCHITECTURE AND ELECTRONIC DEVICE RELATED THERETO

(71) Applicant: PanelSemi Corporation, New Taipei City (TW)

(72) Inventor: Chin-Tang LI, New Taipei City (TW)

(21) Appl. No.: 19/450,945

(22) Filed: Jan. 16, 2026

Related U.S. Application Data
(60) Provisional application No. 63/746,024, filed on Jan. 16, 2025.
(60) Provisional application No. 63/813,077, filed on May 28, 2025.

(51) Int. Cl. H10W 70/60; H10W 70/68; H10W 74/10; H10W 90/10

(52) U.S. Cl. CPC H10W 70/618; H10W 70/682; H10W 74/117; H10W 90/10

(57) ABSTRACT

A substrate architecture is disclosed, comprising a bridging substrate, a function chip unit, and a filling material. The bridging substrate defines a coefficient of thermal expansion (CTE) no greater than 10 ppm/° C. along a horizontal plane thereof and has a passage. The function chip unit is at least partially accommodated in the passage, with a gap derived between the function chip unit and the bridging substrate. The filling material is arranged in the gap. By controlling the CTE of the bridging substrate and integrating the function chip unit within the passage, the substrate architecture effectively addresses thermal stress issues and enhances structural integration.

### CROSS REFERENCE TO RELATED APPLICATIONS

This Non-provisional application which claims priority under 35 U.S.C. § 119(a) on Patent Application No(s). 63/746,024 filed in United States of America on Jan. 16, 2025, and on Patent Application No(s). 63/813,077 filed in United States of America on May 28, 2025, the entire contents of which are hereby incorporated by reference.

### BACKGROUND

### Technology Field

The present invention relates to a substrate architecture, which can be applied in the field of semiconductor packaging or other electronic components.

### Description of Related Art

As electronic products trend towards smaller and thinner designs, semiconductor packaging technologies continue to evolve. While these packaging technologies each have their unique characteristics, they still face numerous technical bottlenecks and challenges. The primary concern lies in the difference in Coefficient of Thermal Expansion (CTE) between different materials within the package structure. When electronic devices undergo temperature changes during operation, the thermal expansion mismatch between materials leads to internal stress accumulation, resulting in structural warpage, interface delamination, and other reliability issues. Furthermore, as chip performance improves, traditional electrical interconnection methods can no longer meet high-speed transmission requirements. Long conductive paths not only cause signal loss but may also introduce serious crosstalk interference, limiting overall transmission bandwidth. Moreover, purely electrical connection architectures also restrict future possibilities for optoelectronic integration. In terms of packaging density, existing technologies often struggle to achieve high functional integration within limited space. From a manufacturing perspective, current packaging technologies generally require extremely high alignment precision and involve complex process steps, which not only affects yield but also increases production costs. The complicated process flow also increases potential failure risks, impacting product stability and consistency. In view of this, the industry urgently needs a new type of packaging structure that can simultaneously address the aforementioned technical challenges, while effectively managing thermal stress, enhancing signal transmission performance, increasing integration density, and improving process feasibility and reliability performance.

### SUMMARY

One aspect of the present invention is to provide a substrate architecture and one or more exemplary embodiments thereof, all of which demonstrate a manufacturing method for the substrate structure that simultaneously addresses thermal stress risks while reducing manufacturing costs

The present invention is to provide a substrate architecture comprising: a bridging substrate, defining a coefficient of thermal expansion (CTE) no greater than 10 ppm/° C. along a horizontal plane thereof; wherein the bridging substrate has a passage; a function chip unit at least partially accommodated in the passage; a gap derived between the function chip unit and the bridging substrate; and a filling material arranged in the gap.

In some embodiments, the bridging substrate is a single-layer substrate.

In some embodiments, the bridging substrate is a multi-layer substrate.

In some embodiments, the bridging substrate includes glass, Silica (silicon dioxide, SiO₂), ceramic, glass-ceramic, compound semiconductor material, or polyimide, or a combination of one or more of the above materials.

In some embodiments, the passage communicates with two sides of the bridging substrate.

In some embodiments, the function chip unit is accommodated within the passage, each of the bridging substrate and the function chip unit defines a thickness, and the thickness of the function chip unit approaches the thickness of the bridging substrate.

In some embodiments, the coefficient of thermal expansion of the bridging substrate is no greater than 8 ppm/° C. along the horizontal plane.

In some embodiments, the coefficient of thermal expansion of the bridging substrate is no greater than 4 ppm/° C. along the horizontal plane.

In some embodiments, the function chip unit retaining against the filling material along the horizontal plane.

In some embodiments, the function chip unit defines a coefficient of thermal expansion (CTE) along the horizontal plane; a ratio of the CTE of the bridging substrate to the CTE of the function chip unit is no less than 0.5.

In some embodiments, the function chip unit defines a coefficient of thermal expansion (CTE) along the horizontal plane; a ratio of the CTE of the bridging substrate to the CTE of the function chip unit is no greater than 2.5.

In some embodiments, the filling material defines a coefficient of thermal expansion (CTE) along the horizontal plane; the CTE of the filling material is greater than both the CTE of the bridging substrate and the CTE of the function chip unit.

In some embodiments, the function chip unit includes one or more function chips.

In some embodiments, the functional chip unit includes one or more bridge dies (BD), deep trench capacitors (DTC), voltage regulators (VR), integrated passive devices (IPD), EIC, PIC or optoelectronic elements, or a combination of one or more of the above components.

In some embodiments, the optoelectronic element is a transmitter and/or a photo sensor.

In some embodiments, the photo transmitter is a light-emitting diode (LED) or a laser diode (LD).

In some embodiments, the substrate architecture further includes a material property layer arranged at a side of the bridging structure, at least partially covering the gap, and connecting the filling material.

In some embodiments, among the material property layer, the filling material, and the bridging substrate, at least two of them include the same material.

In some embodiments, the material property layer includes Polyimide.

In some embodiments, the material property layer defines a coefficient of thermal expansion (CTE) along the horizontal plane, and a difference between the coefficient of thermal expansion of the material property layer and the coefficient of thermal expansion of the bridging substrate does not exceed 1.3 ppm/° C.

In some embodiments, the material property layer defines a coefficient of thermal expansion (CTE) along the horizontal plane, and a difference between the coefficient of thermal expansion of the material property layer and the coefficient of thermal expansion of the bridging substrate is not less than 0.7 ppm/° C.

In some embodiments, the material property layer bonds the bridging substrate and is arranged in a consecutive and discontinuous manner along the horizontal plane.

In some embodiments, the material property layer bonds the bridging substrate and is arranged in a planar manner along the horizontal plane.

In some embodiments, the substrate architecture further includes a conductive member arranged through the bridging substrate and individual from the passage.

In some embodiments, the substrate architecture further includes a layer structure at least partially covering one of the two sides of the bridging substrate, the gap, and the bridging chip unit; wherein the layer structure is in communication with the bridging chip unit by at least one type of electrical signals and optical signals.

In some embodiments, the substrate architecture further includes a conductive member arranged through the bridging substrate and individual from the passage, wherein the conductive member electrically connects the layer structure.

In some embodiments, the layer structure defines a dielectric loss (Df) of no greater than 0.006 at a frequency of 10 GHz.

In some embodiments, the layer structure extends across and at least partially covers the gap.

In some embodiments, the layer structure includes a material layer and one or more communication layers combined with the material layer; the communication layer or at least partial of the communication layers extends across and at least partially covers the gap.

In some embodiments, the substrate architecture further includes an opposite layer structure at least partially covers an opposite side of the bridging substrate, the gap, and the function chip unit and counter to the layer structure; the opposite layer structure communicates with the function chip unit by at least one type of electrical signals and optical signals.

In some embodiments, the opposite layer structure defines a dielectric loss (Df) of no greater than 0.006 at a frequency of 10 GHz.

In some embodiments, the layer structure extends across and at least partially covers the gap.

In some embodiments, the opposite layer structure includes a material layer and one or more communication layers combined with the material layer; the communication layer or at least partial of the communication layers extends across and at least partially covers the gap.

In some embodiments, the layer structure includes a waveguide structure optically coupling to the function chip unit.

In some embodiments, the opposite layer structure includes a waveguide structure optically coupling to the function chip unit.

In some embodiments, the layer structure and the opposite layer structure are asymmetric structures.

In some embodiments, an absolute difference ratio of the total volume expansion within a plane range of the bridging substrate between the layer structure and the opposite layer structure is not less than 30%.

In some embodiments, the function chip unit includes one or more photo transmitter and/or one or more photo sensor.

In some embodiments, the photo transmitter and/or photo sensor is arranged to face the waveguide structure.

In some embodiments, the function chip unit defines a line width no greater than 1 μm on a side thereof facing the layer structure.

In some embodiments, the function chip unit defines a line space no greater than 1 μm on a side thereof facing the layer structure.

In some embodiments, the function chip unit defines a line width no greater than 1 μm on a side thereof facing the opposite layer structure.

In some embodiments, the function chip unit defines a line space no greater than 1 μm on a side thereof facing the opposite layer structure.

In some embodiments, the substrate architecture further includes a conductive member arranged through the bridging substrate and individual from the passage, wherein the conductive member electrically connects the layer structure and the opposite layer structure.

In some embodiments, the substrate architecture further includes an opposite material property layer arranged between the opposite layer structure and the bridging substrate, wherein the opposite material property layer connects the filling material.

In some embodiments, material(s) of the opposite material property layer and the filling material is(are) identical.

In some embodiments, the material property layer includes Polyimide.

In some embodiments, the opposite material property layer bonds the bridging substrate and is arranged in a consecutive and discontinuous manner along the horizontal plane.

In some embodiments, the material property layer bonds the bridging substrate and is arranged in a planar manner along the horizontal plane.

In some embodiments, the bridging substrate is a multi-layer substrate, including multiple substrate layers and one or more adhesive layers bonding adjacent two of the substrate layers.

In some embodiments, the conductive member, in a vertical direction perpendicular to the horizontal plane, includes multiple sub-conductive members penetrating through the substrate layers, and a conductive material bonding adjacent two of the sub-conductive members.

In some embodiments, the bridging substrate includes a conductive layer arranged on the substrate layer or at least ones of the substrate layers, wherein the conductive material electrically connects to the corresponding sub-conductive member(s) through the conductive layer.

In some embodiments, the filling material includes Silica, ceramic, glass-ceramic, glass frit, glass powder, glass paste, Epoxy, silicone, or Polyimide (PI), or a combination of one or more of the above materials.

In some embodiments, the material property layer includes Silica, ceramic, glass-ceramic, glass frit, glass powder, glass paste, Epoxy, silicone, or Polyimide (PI), or a combination of one or more of the above materials.

In some embodiments, the adhesive layer includes glass frit, glass powder, glass paste, or a combination of one or more of the above materials.

In some embodiments, the substrate architecture further includes a temporary carrier board connected to the bridging substrate.

In some embodiments, the substrate architecture further includes a temporary carrier board connected to the bridging substrate through the layer structure.

In some embodiments, the temporary carrier board is or includes a glass substrate.

In some embodiments, the bridging substrate defines one or more corners or edges; the material property layer is arranged in a planar manner along the horizontal plane of the bridging substrate, and the material property layer wraps at least one of the edges.

In some embodiments, the bridging substrate defines one or more corners or edges, and a chamfer disposed at one of the corners or edges; the material property layer is arranged in a planar manner along the horizontal plane of the bridging substrate, and the material property layer wraps the chamfer.

In some embodiments, the substrate architecture further includes a conductive member, being independent of the passage, penetrating through the bridging substrate and the filling material, and electrically connecting to the layer structure.

The present invention provides a stacked substrate architecture comprising: a packaged substrate; and a substrate architecture as claimed in any one of claims 1 to 61, stacked on the packaged substrate; wherein the functional chip unit of the substrate architecture communicates with the packaged substrate through at least one of electrical signals and optical signals.

In some embodiments, the packaged substrate comprises glass, Silica (silicon dioxide, SiO₂), ceramic, glass-ceramic, compound semiconductor material, polyimide, BT, FR4, or a combination of one or more of the above materials.

In some embodiments, the packaged substrate comprises at least one of a waveguide structure and an electrical layer.

The present invention provides an electronic device comprising: a substrate; a substrate architecture as claimed in any of claims 1 to 61, stacked to the substrate; a plurality of electronic components, arranged at a side of the substrate architecture in communication with the function chip unit through the layer structure, wherein the communication includes at least one type of electrical signals and optical signals; and a plurality of external conductive components, arranged at an opposite side of the substrate architecture, wherein the external conductive components are arranged between and electrically connected with the substrate architecture and the substrate.

In some embodiments, one of the electronic components includes a HBM (High Bandwidth Memory), or a Switch, or a NPU (Neural Processing Unit), TPU (Tensor Processing Unit), CPU (Central Processing Unit), or a GPU (Graphics Processing Unit), or any combination containing any component thereof.

In some embodiments, one of the electronic components includes a photosensitive component, or an optoelectronic conversion component, or any combination containing any component thereof.

In some embodiments, one of the electronic components defines a line width no greater than 1 μm on a face thereof facing the layer structure.

In some embodiments, one of the electronic components defines a line space no greater than 1 μm on a face thereof facing the layer structure.

In some embodiments, the electronic device further includes a protection layer covering the electronic components and connected to the substrate architecture.

The foregoing is merely illustrative and not intended to limit the present invention. In addition to the illustrative embodiments, examples, and features described above, other embodiments, examples, and features of the present invention can be clearly understood by referring to the drawings and the following detailed description.

### BRIEF DESCRIPTION OF THE DRAWINGS

FIG. 1A is a schematic cross-sectional view of a substrate architecture 100A according to a first embodiment of the present invention.

FIG. 1B is a schematic cross-sectional view of a substrate architecture 100B according to another embodiment of the present invention.

FIG. 1C is a schematic cross-sectional view of a substrate architecture 100C according to another embodiment of the present invention.

FIG. 1D is a schematic cross-sectional view of a substrate architecture 100D according to another embodiment of the present invention.

FIG. 1E is a schematic cross-sectional view of a substrate architecture 100E according to another embodiment of the present invention.

FIG. 2A is a schematic cross-sectional view of a substrate architecture 100F according to an embodiment of the present invention.

FIG. 2B is a schematic cross-sectional view of a substrate architecture 100G according to an embodiment of the present invention.

FIG. 2C is a schematic cross-sectional view of a substrate architecture 100H according to an embodiment of the present invention.

FIG. 2D is a schematic cross-sectional view of a substrate architecture 100I according to an embodiment of the present invention.

FIG. 2E is a schematic cross-sectional view of a substrate architecture 100J according to an embodiment of the present invention.

FIG. 3A is a schematic cross-sectional view of a substrate architecture 200A according to an embodiment of the present invention.

FIG. 3B is a schematic cross-sectional view of a substrate architecture 200B according to an embodiment of the present invention.

FIG. 3C is a schematic cross-sectional view of a substrate architecture 200C according to an embodiment of the present invention.

FIG. 3D is a schematic cross-sectional view of a substrate architecture 200D according to an embodiment of the present invention.

FIG. 3E is a schematic cross-sectional view of a substrate architecture 200E according to an embodiment of the present invention.

FIG. 4 is a schematic cross-sectional view of a stacked substrate architecture according to an embodiment of the present invention.

FIG. 5A is a schematic cross-sectional view of an electronic device I according to an embodiment of the present invention.

FIG. 5B is a schematic cross-sectional view of an electronic device II according to an embodiment of the present invention.

FIG. 5C is a schematic cross-sectional view of an electronic device III according to an embodiment of the present invention.

FIG. 5D is a schematic cross-sectional view of an electronic device IV according to an embodiment of the present invention.

FIG. 6 is a schematic cross-sectional view of an electronic device V according to an embodiment of the present invention.

FIGS. 7A to 7G are schematic views showing a manufacturing process of a substrate architecture 100K according to an embodiment of the present invention.

FIG. 8A is a schematic cross-sectional view of a substrate architecture 100L according to an embodiment of the present invention.

FIG. 8B is a schematic cross-sectional view of a substrate architecture 100M according to an embodiment of the present invention.

FIG. 8C is a schematic cross-sectional view of a substrate architecture 100N according to an embodiment of the present invention.

### DETAILED DESCRIPTION OF THE DISCLOSURE

The following description will refer to relevant drawings to explain the substrate assembly according to the preferred embodiments of this invention, wherein the same elements will be described using the same reference symbols.

The advantages, features, and implementation methods of the present invention will be clearly explained in the following embodiments with reference to the drawings. However, the present invention may be embodied in various forms and should not be construed as being limited to the embodiments described herein. Rather, these embodiments are provided to make this specification thorough and complete, and to fully convey the scope of the disclosure to those skilled in the art. The scope of the present invention should be defined only by the appended claims. Therefore, well-known components, operations, and techniques are not described in detail in the embodiments to avoid obscuring the technical features of the disclosure. Throughout the specification, identical or similar elements are denoted by identical or similar reference symbols. When an element is referred to as being “connected” to another element, it may be “directly or indirectly mechanically connected” to, or “electrically connected” to the other element, and one or more intervening elements may be present therebetween. It is to be understood that in this specification, the terms “include” or “comprise” specify the stated features, integers, steps, operations, elements and/or components, but do not preclude the presence or addition of one or more other features, integers, steps, operations, elements and/or components, or any combination thereof. The term “and/or” or “or/and” indicates the possibility of intersection or union of one or more other features, integers, steps, operations, elements and components, or any combination thereof. Unless otherwise defined, all terms used in this specification (including technical and scientific terms) have the same meanings as commonly understood by those skilled in the art to which the present invention pertains. Further, terms, including those defined in commonly used dictionaries, should be interpreted as having meanings consistent with their meaning in the context of the relevant art and will not be interpreted in an idealized or overly rigorous sense unless explicitly defined herein.

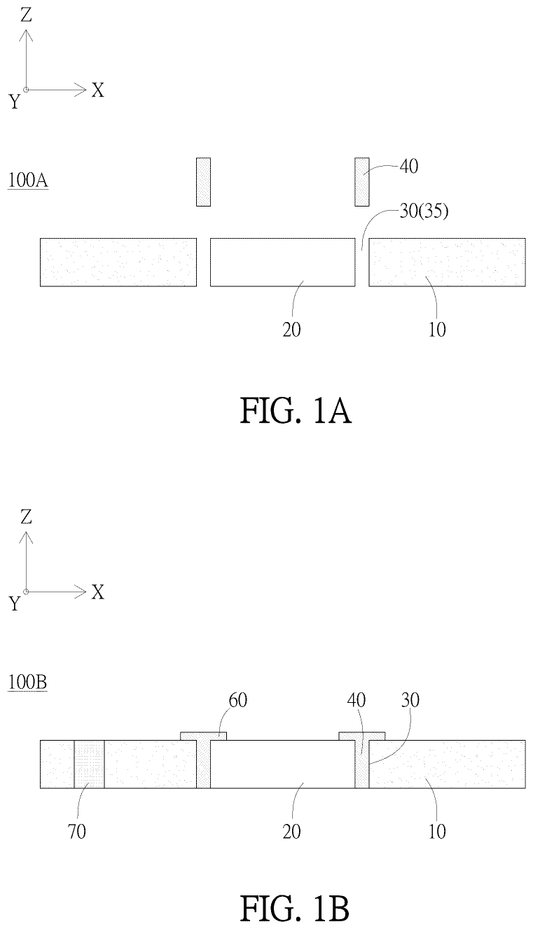

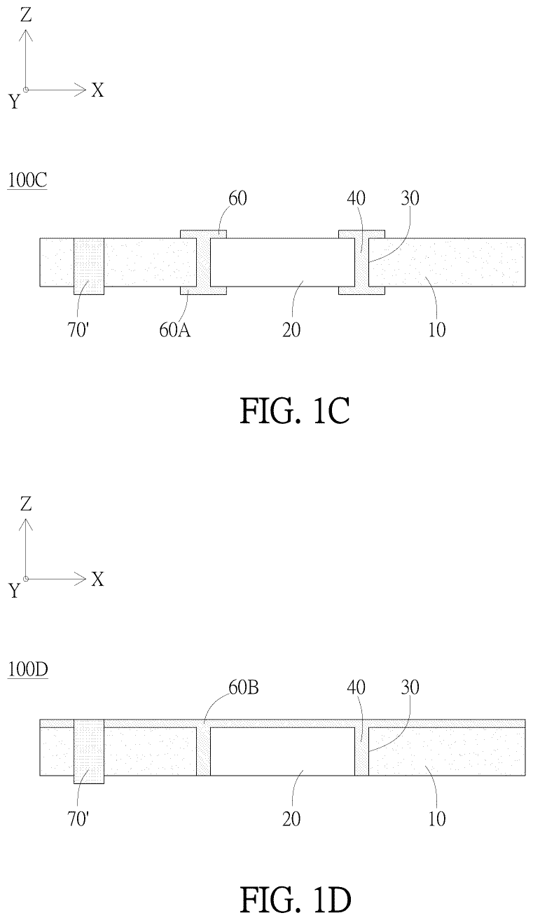

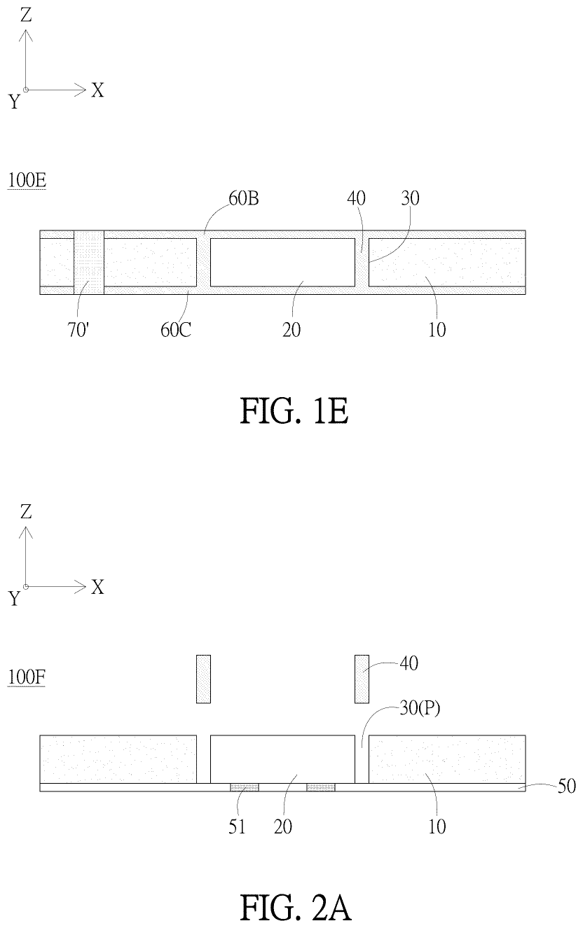

Referring to FIG. 1A, a substrate architecture 100A according to the first embodiment of the present invention is shown. The substrate architecture 100A includes a bridging substrate 10, a function chip unit 20, a gap 30, and a filling material 40. The bridging substrate 10 defines a coefficient of thermal expansion (CTE) no greater than 8 ppm/° C. along a horizontal plane (X-Y plane); the bridging substrate 10 has a passage 35. The function chip unit 20 is at least partially accommodated in the passage 35. The gap 30 is derived between the function chip unit 20 and the bridging substrate 10. The filling material 40 is arranged in the gap 30.

The bridging substrate 10 may be a single-layer or multi-layer substrate (for example, a composite board). In some embodiments, the bridging substrate 10 may include organic material, or at least one layer thereof contains organic material. In some embodiments, the bridging substrate 10 may include glass, Silica (silicon dioxide, SiO₂), ceramic, glass-ceramic, compound semiconductor material, or polyimide, or a combination of one or more of the above materials. As shown in the FIG, there may be multiple passages 35, and the number of corresponding components increases accordingly. The passage 35 may communicate with both sides of the bridging substrate 10, may communicate with only one side of the bridging substrate 10, or may not communicate with either side of the bridging substrate 10, and is not limited thereto.

The function chip unit 20 includes one or more chips, and may be accommodated in the passage 35 in either modular or non-modular form. Each of the bridging substrate 10 and the function chip unit 20 defines a thickness, with the thickness of the function chip unit 20 approaching the thickness of the bridging substrate 10; typically, the function chip unit 20 is completely accommodated within the passage 35 for subsequent processing advantages, thus the thickness of the function chip unit 20 is no greater than that of the bridging substrate 10. The function chip unit 20 retains against the filling material 40 along the horizontal plane. The function chip unit 20 includes one or more bridge dies (BD), deep trench capacitors (DTC), voltage regulators (VR), integrated passive devices (IPD), electrical integrated circuits (EIC), photonic integrated circuits (PIC), or optoelectronic elements, or a combination of one or more of the above components and materials, but is not limited thereto. The optoelectronic element includes a photo transmitter and/or a photo sensor. The photo transmitter is a light-emitting diode (LED), an organic light-emitting diode (OLED), or a laser diode (LD).

The filling material 40 includes Silica (silicon dioxide, SiO₂), ceramic, glass-ceramic, glass frit, glass powder, glass paste, Epoxy, silicone, or Polyimide (PI), or a combination of one or more of these materials.

In the substrate architecture 100B shown in FIG. 1B, the substrate architecture 100B further includes a material property layer 60, positioned on at least one side of the bridging substrate 10 and connected to the filling material 40; the material property layer 60 may at least partially cover the gap 30. The material property layer 60 includes glass, Silica (silicon dioxide, SiO₂), ceramic, glass-ceramic, glass frit, glass powder, glass paste, compound semiconductor material, or Epoxy, silicone, or polyimide, or a combination of one or more of these materials. In one embodiment, at least two of the material property layer 60, the filling material 40, and the bridging substrate 10 may comprise the same or different materials, for example, including polyimide, epoxy resin, or silicone material; however, it is not limited thereto. The material property layer 60 connects to the bridging substrate 10 and is arranged in a consecutive and discontinuous manner along the horizontal plane of the bridging substrate 10; or, is arranged in a planar manner along the horizontal plane. As shown in FIG. 1B, the material property layer 60 is arranged in a consecutive and discontinuous manner along the horizontal plane of the bridging substrate 10. Additionally, the substrate architecture 100B further includes a conductive member 70, independent from the passage 35 and penetrating through the bridging substrate 10; the conductive member 70 may be a single structure or a composite structure combined from multiple sub-components.

In the substrate architecture 100C shown in FIG. 1C, two material property layers 60, 60A are arranged on both opposite sides of the bridging substrate 10. The conductive member 70A is independent from the passage 35 and penetrates through the bridging substrate 10. The two material property layers 60, 60A are arranged in a consecutive and discontinuous manner along the horizontal plane of the bridging substrate 10 and at least partially cover the passage 35.

In the substrate architecture 100D shown in FIG. 1D, the material property layer 60B is arranged in a planar manner along the horizontal plane of the bridging substrate 10, and the material property layer 60B may be attached to the bridging substrate 10 in the form of a thin plate or film.

In the substrate architecture 100E shown in FIG. 1E, two material property layers 60B, 60C are arranged on both opposite sides of the bridging substrate 10, arranged in a planar manner along the horizontal plane of the bridging substrate 10.

The above-mentioned embodiments can be combined in various arrangements.

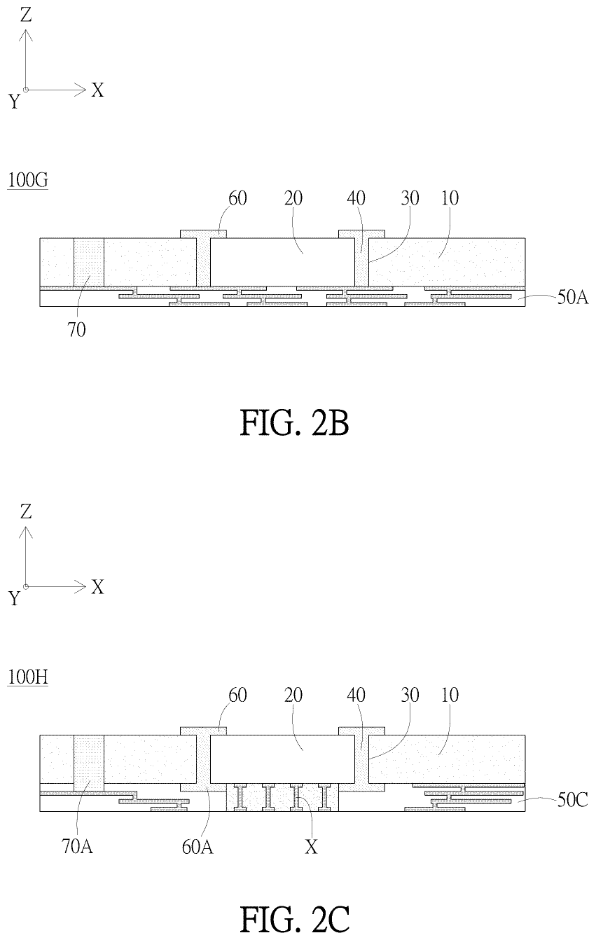

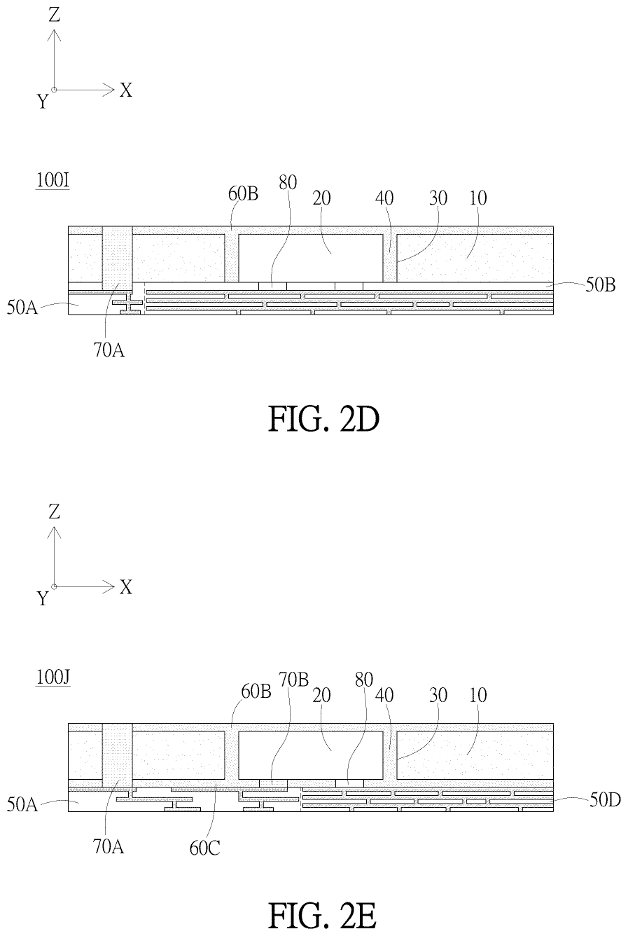

The difference between the series FIG. 2 and series FIG. 1 is the addition of the layer structure. The details are as follows:

Referring to FIG. 2A, a substrate architecture 100F according to the first embodiment of the present invention is shown. The substrate architecture 100F includes a bridging substrate 10, a function chip unit 20, a gap 30, a filling material 40, and a layer structure 50. The bridging substrate 10 defines a coefficient of thermal expansion (CTE) no greater than 8 ppm/° C. along a horizontal plane (X-Y plane); the bridging substrate 10 has a passage 35 that communicates between both sides. The function chip unit 20 is at least partially accommodated in the passage 35. The gap 30 is derived between the function chip unit 20 and the bridging substrate 10. The filling material 40 is arranged in the gap 30. The layer structure 50 at least partially covers one side of the bridging substrate 10, gap 30, and function chip unit 20; wherein the layer structure 50 and the function chip unit 20 can communicate through at least one of electrical signals and optical signals. In this embodiment, the layer structure 50 is located on the same side (bottom side) of the bridging substrate 10, gap 30, and function chip unit 20.

The layer structure 50 spans across and at least partially covers the gap 30. The layer structure 50 includes one or more layers of layer materials, with at least one layer being of the same material as the bridging substrate 10. The layer structure 50 includes layer materials and one or more communication layers combined with the layer materials. In some embodiments, the functional chip unit 20 has a line width of not greater than 1 μm on the side facing the layer structure 50. The functional chip unit 20 has a line spacing of not greater than 1 μm on the side facing the layer structure 50. The layer structure 50 is defined to have a dielectric loss (Df) of not greater than 0.006 at a frequency of 10 GHz. In FIG. 2A, the layer structure 50 includes a layer material and a communication layer 51 combined with the layer material, where the communication layer 51 is an electrical layer and is electrically connected to the function chip unit 20.

The coefficient of thermal expansion (CTE) of the bridging substrate 10 may be no greater than 4 ppm/° C. along the horizontal plane. In one case, the function chip unit 20 defines a coefficient of thermal expansion (CTE) along the horizontal plane; the ratio of the CTE of the bridging substrate 10 to the CTE of the function chip unit 20 is not less than 0.5. In another case; the ratio of the CTE of the bridging substrate 10 to the CTE of the function chip unit 20 is not greater than 2.5. The filling material 40 may define a coefficient of thermal expansion (CTE) along the horizontal plane; the CTE of the filling material 40 is greater than both the CTE of the bridging substrate 10 and the CTE of the function chip unit 20.

In the substrate architecture 100G shown in FIG. 2B, the layer structure 50A includes a communication layer serving as a redistribution layer (RDL). Additionally, the substrate architecture 100G further includes a material property layer 60, positioned on at least one side of the bridging substrate 10 and connected to the filling material 40; the material property layer 60 may be located between the layer structure 50A and the bridging substrate 10, and may at least partially cover the gap 30. The material property layer 60 and the filling material 40 may be of the same material (for example, materials of the same composition configured by independent processes, or the material property layer 60 being an extension of a portion of the filling material 40), and the material property layer 60 and the bridging substrate 10 may also be made of the same material (for example, materials of the same composition configured by independent processes). The materials or combination of materials of the material property layer 60 may refer to the aforementioned descriptions. The material property layer 60 may be located on the same or different side of the bridging substrate 10 as the layer structure 50A. The material property layer 60 connects to the bridging substrate 10 and is arranged in a consecutive and discontinuous manner along the horizontal plane of the bridging substrate 10; or, is arranged in a planar manner along the horizontal plane. As shown in FIG. 2B, the material property layer 60 is arranged in a consecutive and discontinuous manner along the horizontal plane of the bridging substrate 10. Furthermore, the substrate architecture 100G includes a conductive member 70, independent from the passage 35, penetrating through the bridging substrate 10, and electrically connected to the redistribution layer (RDL) of the layer structure 50A.

In the substrate architecture 100H shown in FIG. 2C, two material property layers 60, 60A are arranged on both opposite sides of the bridging substrate 10. In this embodiment, the material property layer 60A is located between the bridging board 10 and the layer structure 50B. In addition, the layer structure 50B includes a communication layer, which at least includes a redistribution layer (RDL), and a plurality of conductive members 70C penetrating through the layer structure 50B and electrically connecting to the functional chip unit 20. As mentioned above, the layer structure 50B includes one or more stacked layer materials and one or more communication layers combined with the layer materials; the communication layer may include the redistribution layer (RDL) and the conductive members 70C electrically communicating along the Z direction. The conductive members 70A are electrically connected to the redistribution layer (RDL) of the layer structure 50B. In this embodiment, the conductive members 70C are arranged corresponding to the functional chip unit 20, and the redistribution layer (RDL) is arranged at least to a part of the functional chip unit 20 and the bridging board 10.

In the board structure 100I of FIG. 2D, the material property layer 60B is arranged in a planar manner along a horizontal plane of the bridging board 10. In addition, the layer structure 50C includes one or more stacked layer materials and one or more communication layers combined with the layer materials; the communication layer at least includes an electrical layer and an optical layer; the electrical layer may be a redistribution layer (RDL) electrically connected to the conductive members 70A disposed on the bridging board 10, and the optical layer is a waveguide structure 55 coupled to the functional chip unit 20 through an optical channel 80A.

In the board structure 100J of FIG. 2E, two material property layers 60A and 60C are respectively disposed on opposite sides of the bridging board 10, and are arranged in a planar manner along a horizontal plane of the bridging board 10. In addition, the layer structure 50D includes one or more stacked layer materials and one or more communication layers combined with the layer materials; the communication layer at least includes an electrical layer and an optical layer; the electrical layer may be a redistribution layer (RDL) electrically connected to the conductive members 70A disposed on the bridging board 10 and electrically connected to the conductive members 70B coupled to the functional chip unit 20, and the optical layer is a waveguide structure 55 coupled to the functional chip unit 20 through an optical channel 80. In some embodiments, the material property layer 60 is connected to the layer structure 50D; the layer materials of the material property layer 60 and the layer structure 50D may be different materials and implemented in different steps, or may be the same material and implemented in the same step. In another embodiment, the material property layer 60 may define a coefficient of thermal expansion (CTE) along the horizontal plane, and a difference between the CTE of the material property layer 60 and the CTE of the bridging board 10 is not greater than 1.3 ppm/° C. In another embodiment, the difference between the CTE of the material property layer 60 and the CTE of the bridging board is not less than 0.7 ppm/° C. In some embodiments where the electrical layer 50 is integrated into the material property layer 60, the CTE of the material property layer 60 may be broadly interpreted as an equivalent CTE of the material property layer 60 and the electrical layer 50; similarly, referencing that the bridging board 10 is a multi-layer board at this time generating an equivalent CTE, a difference between the equivalent CTE of the material property layer 60 and the equivalent CTE of the bridging board 10 is not greater than 1.3 ppm/° C.; in another embodiment, the difference between the equivalent CTE of the material property layer 60 and the equivalent CTE of the bridging board is not less than 0.7 ppm/° C. Please note that this description is not a necessary embodiment, but merely illustrates that the equivalent CTE derived from multi-layer or integration can be considered equivalent.

The above-mentioned embodiments can be combined in various arrangements.

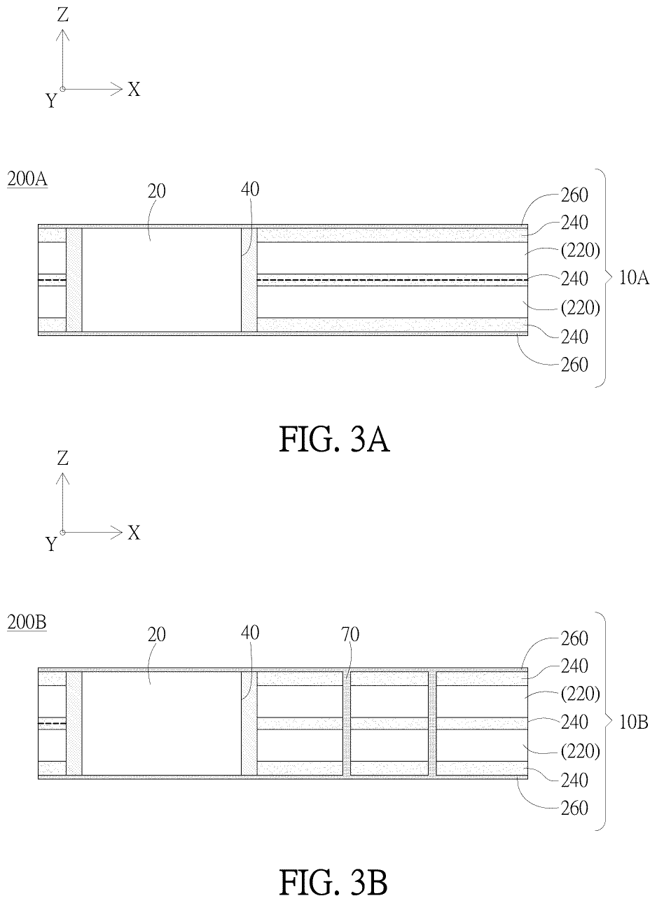

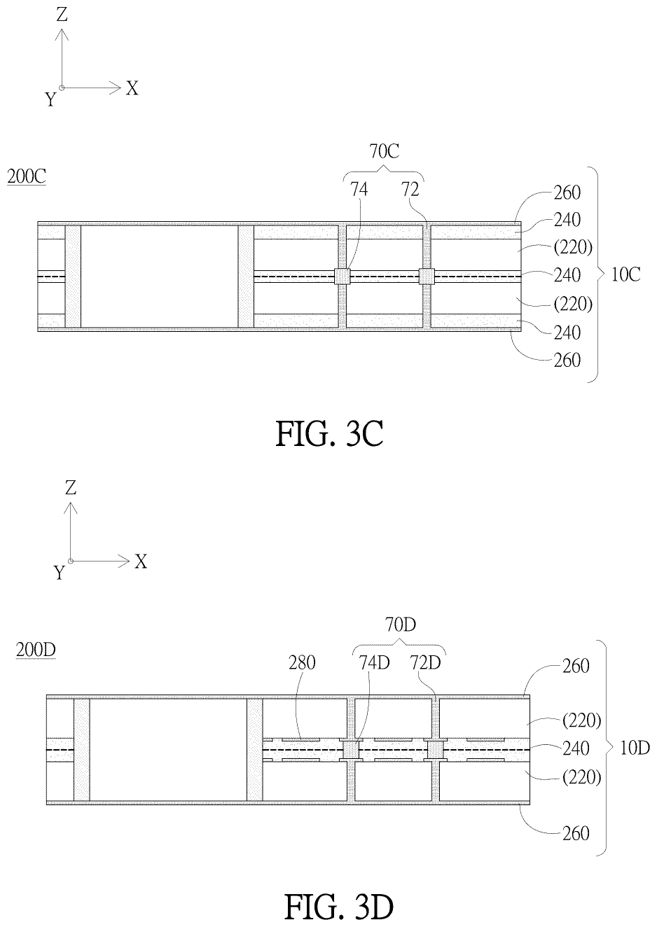

The series FIG. 3 shows the diversity of the bridging substrate itself. In the substrate architecture 200A shown in FIG. 3A, the bridging substrate 10A is a multi-layer substrate, including multiple substrate materials 220 and one or more adhesive layers 240 bonding these substrate materials. The bridging substrate 10A further has electrical layers 260 arranged on the outermost sides of the substrate materials 220. This electrical layer 260 can be an independent component configuration combined with the bridging substrate 10A, or a layer structure matching the bridging substrate 10A. For ease of understanding, taking the configuration of this electrical layer 260 combined with the bridging substrate 10A as an example, the electrical layer 260 can be bonded to the bridging substrate 10A through the adhesive layer 240. The function chip unit 20 is set in the channel of the bridging substrate 10A as in the previous embodiments. Using Polyimide (PI) as an example for the substrate material 220, the adhesive layer 240 includes glass frit, glass powder, glass paste, or a combination of one or more of these materials.

In the substrate architecture 200B shown in FIG. 3B, the conductive member 70 penetrates through the bridging substrate 10B, connecting both sides of the bridging substrate 10B. Here, the conductive member 70 is a single structure electrically connecting the electrical layers 260 on both sides.

In the substrate architecture 200C shown in FIG. 3C, the conductive member 70D penetrates through the bridging substrate 10C, connecting both sides of the bridging substrate 10C. Here, the conductive member 70D is a composite structure electrically connecting the electrical layers 260 on both sides. The conductive member 70D includes multiple sub-conductive members 72 penetrating through the substrate materials 220 along the vertical direction Z of the vertical plane, and a conductive material 74 joining adjacent sub-conductive members 72.

In the substrate architecture 200D shown in FIG. 3D, the electrical layer 260 is not bonded to the bridging substrate 10D through the adhesive layer 240 (the adhesive layer 240 adjacent to the electrical layer 260 does not exist). The conductive member 70E penetrates through the bridging substrate 10D, connecting both sides of the bridging substrate 10D. Here, the conductive member 70E is a composite structure electrically connecting the electrical layers 260 on both sides. The bridging substrate 10D includes one or more conductive layers 280 arranged on the inner surfaces of one or some of the substrate materials 220. Along the vertical direction Z of the vertical plane, the conductive member 70E includes multiple sub-conductive members 72A penetrating through the substrate materials 220, and a conductive material 74A that electrically connects the corresponding sub-conductive member(s) 72A through the conductive layer 280.

The difference between the substrate architecture 200E shown in FIG. 3E and the substrate architecture 200D shown in FIG. 3D is only that the electrical layer 260 is arranged on a single side of the bridging substrate 10E.

The above-mentioned embodiments can be combined in various arrangements.

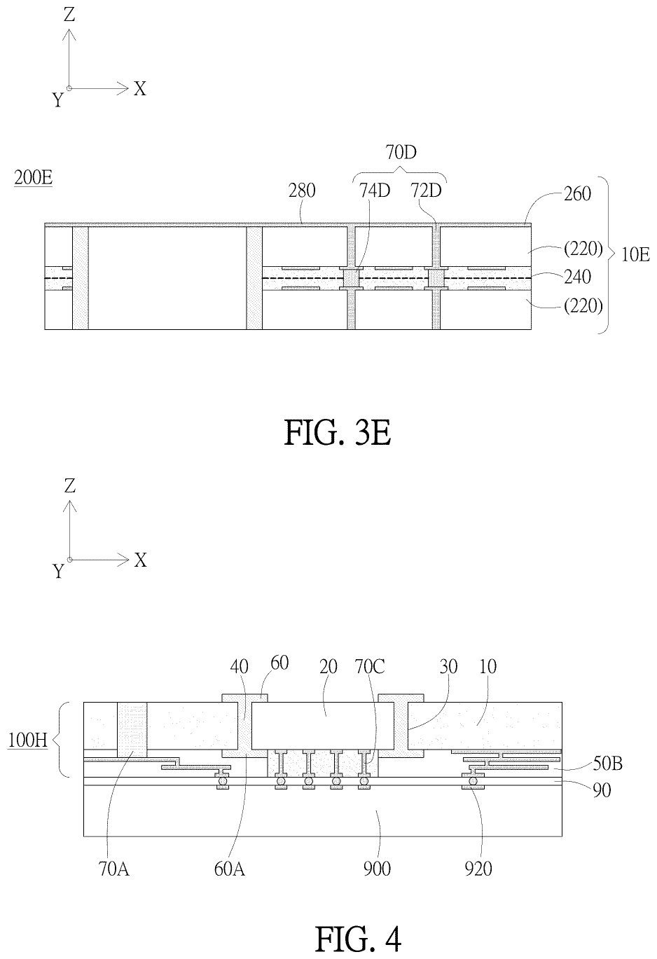

FIG. 4 discloses a stacked substrate architecture, using substrate architecture 100H as an example but not limited to it, further combined with a packaged substrate 900. The substrate architecture 100H is stacked on the packaged substrate 900, and the function chip unit 20 of the substrate architecture can communicate with the packaged substrate 900 through at least one of electrical signals and optical signals. The packaged substrate 900 contains glass, Silica (silicon dioxide, SiO₂), ceramic, glass-ceramic, compound semiconductor material, polyimide, BT, or FR4, or a combination including one or more of these materials. The packaged substrate 900 contains at least one of a waveguide structure and an electrical layer. In the drawings of this embodiment, electrical signals are used as examples.

The above-mentioned embodiments can be combined in various arrangements.

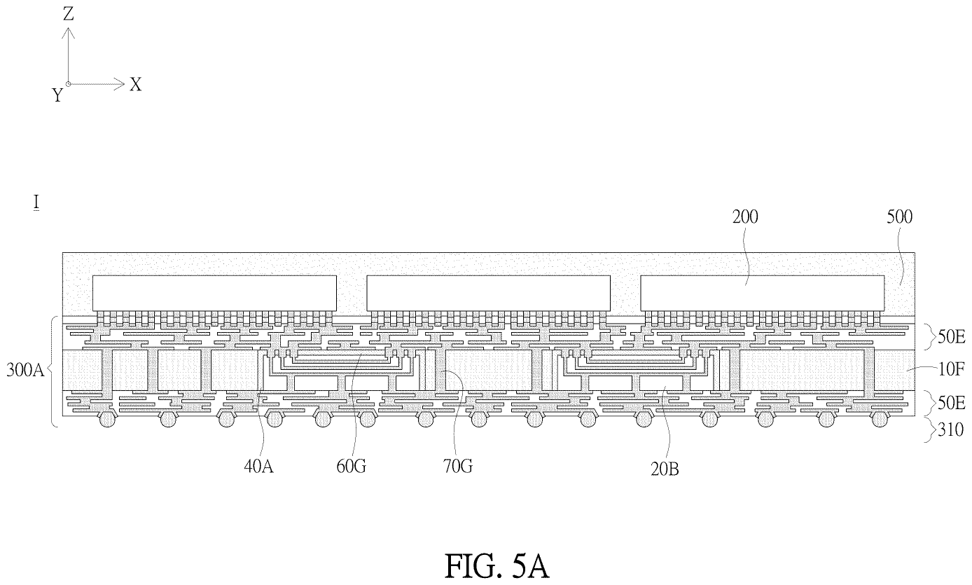

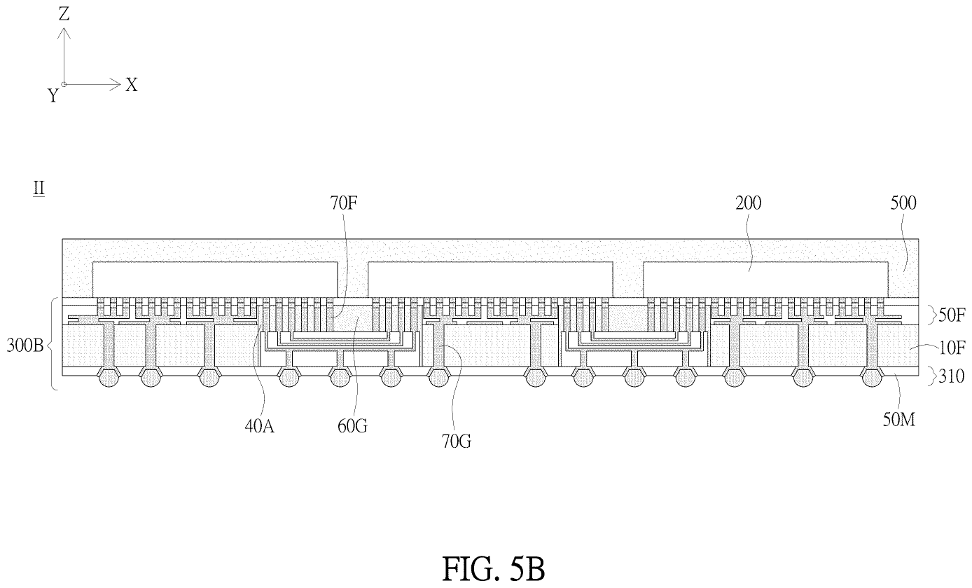

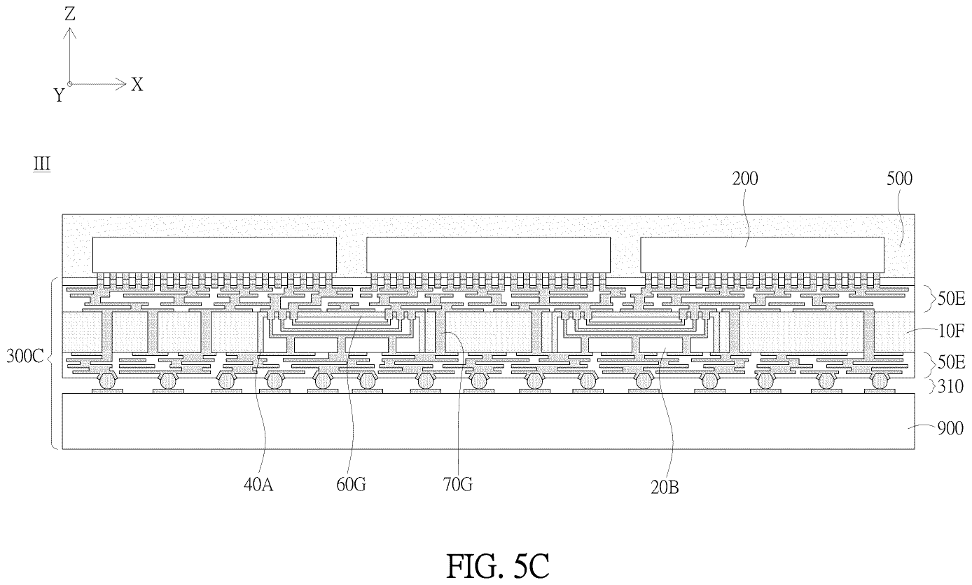

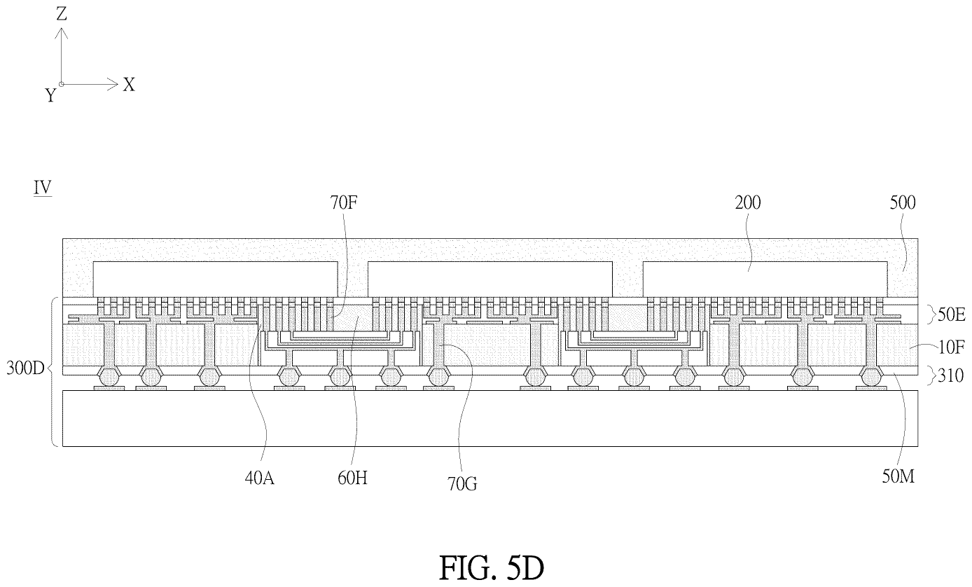

FIGS. 5A and 5B disclose electronic devices I and II, including a substrate architecture, multiple electronic components arranged on one side of the substrate architecture, and multiple external conductive structures arranged on the other side of the substrate architecture.

As shown in FIG. 5A, electronic device I includes a substrate architecture 300A, multiple electronic components 200 arranged on one side of the substrate architecture 300A, multiple external conductive structures 310 arranged on the other side of the substrate architecture 300A, and a protective layer 500 (not an essential component) covering these electronic components 200 and connecting to the substrate architecture 300A. The substrate architecture 300A includes a bridging substrate 10F, one or more function chip units 20B, one or more gaps 30A corresponding to these function chip units 20B, one or more filling materials 40A corresponding to these function chip units 20B, and two layer structures 50A arranged on both sides of the bridging substrate 10F. In some embodiments, the two layer structures 50A are exemplified as symmetric; in this embodiment, the two layer structures 50A are asymmetric. The term “asymmetric structure” means that, with the bridging substrate as the central axis, the structure is asymmetric in terms of electrical or non-electrical properties. Here, it may include a redistribution layer (RDL) or a build-up layer, such as Ajinomoto Build-up Film (ABF), but the present disclosure is not limited to this configuration. For example, the absolute difference ratio of the total volume expansion within a planar range of the bridging substrate between the layer structure 50X and the layer structure 50Y′ is not less than 30%. Each layer structure is not limited to a single layer. The volume expansion of each layer material is measured over a temperature variation range, and for multilayer materials, the total volume expansion is the sum of the volume expansions of each layer over the same temperature variation range. Comparing the two layer structures yields an absolute difference ratio; for example, using the difference as the numerator and the smaller volume expansion change as the denominator, this absolute difference ratio is greater than or equal to 30%. In this embodiment, the layer structures 50A are exemplified as electrical layers (both being redistribution layers), the function chip unit 20B is exemplified as a single bridge chip, and the external conductive structures 310 are exemplified as UBM (Under Bump Metallurgy) and copper bumps. The conductive members 70G configured in the bridging substrate 10F and the function chip unit 20B electrically connect to the layer structures 50A on opposite sides of the bridging substrate 10F. The layer structures 50A on both sides of the bridging substrate 10F have progressively varying line widths or line spacing, with one face of the electronic component 200 facing the layer structures 50A having a line width no greater than 1 μm, and one face of the electronic component 200 facing the layer structures 50A having a line spacing no greater than 1 μm. The electronic components 200 are functional chips, which can be HBM (High-Band Memory), Switch, NPU (Neural Processing Unit), NPU (Neural Processing Unit), TPU (Tensor Processing Unit), CPU (Central Processing Unit), or a GPU (Graphics Processing Unit), or a combination of one or more of these components; or the electronic components 200 can be optical sensing elements, or optoelectronic conversion elements, or a combination of one or more of these components; these implementations can also be combined.

As shown in FIG. 5B, electronic device II includes a substrate architecture 300B, multiple electronic components 200 arranged on one side of the substrate architecture 300B, multiple external conductive structures 310 arranged on the other side of the substrate architecture 300B, and a protective layer 500 (not an essential component) covering these electronic components 200 and connecting to the substrate architecture 300B. The substrate architecture 300B includes a bridging substrate 10F, one or more function chip units 20B, one or more gaps 30A corresponding to these function chip units 20B, one or more filling materials 40A corresponding to these function chip units 20B, and the layer structure 50A arranged on one side of the bridging substrate 10F and the layer structure 50B arranged on the other side. The layer structure 50A is exemplified as electrical layers (partially being redistribution layers and partially including multiple conductive members 70F), while layer structure 50B is exemplified as an insulating layer. Either one or both of the layer structure 50A and the layer structure 50B are defined with a dielectric loss (Df) of no greater than 0.006 at a frequency of 10 GHz. The conductive members 70F of the layer structure 50A are arranged corresponding to the function chip units 20B. The function chip unit 20B is exemplified as a single bridge chip, and the external conductive structures 310 are exemplified as UBM and copper bumps. The conductive member 70G configured in the bridging substrate 10F and the function chip unit 20B electrically connect to the layer structure 50A on one side of the bridging substrate 10F and the external conductive structures 310 on the other side. The layer structure 50A on one side of the bridging substrate 10F has progressively varying line widths or line spacing, with one face of the electronic component 200 facing the layer structure 50A having a line width no greater than 1 μm, and one face of the electronic component 200 facing the layer structure 50A having a line spacing no greater than 1 μm. The electronic components 200 are functional chips, which can be HBM (High-Band Memory), Switch, NPU (Neural Processing Unit), TPU (Tensor Processing Unit), CPU (Central Processing Unit), or GPU (Graphics Processing Unit), or a combination of one or more of these components; or the electronic components 200 can be optical sensing elements, or optoelectronic conversion elements, or a combination of one or more of these components; these implementations can also be combined.

FIGS. 5C and 5D disclose electronic devices III and IV, comprising a board structure 300C, 300D, a plurality of electronic components disposed on one side of a board structure 300A, 300B, a plurality of external conductive structures 310 disposed on the other side of the board structure 300C, 300D, and a package substrate 900 electrically connecting the external conductive structures 310. Compared with the electronic devices I and II disclosed in FIGS. 5A and 5B, the difference lies only in that the electronic devices III and IV have an added package substrate 900. In other words, the stacked board structures 300C and 300D respectively include the board structures 300A and 300B and the package substrate 900. Similarly, the package substrate 900 comprises glass, silica (silicon dioxide, SiO₂), ceramic, glass-ceramic, compound semiconductor material, polyimide, BT, or FR4, or a combination comprising one or more of the foregoing materials.

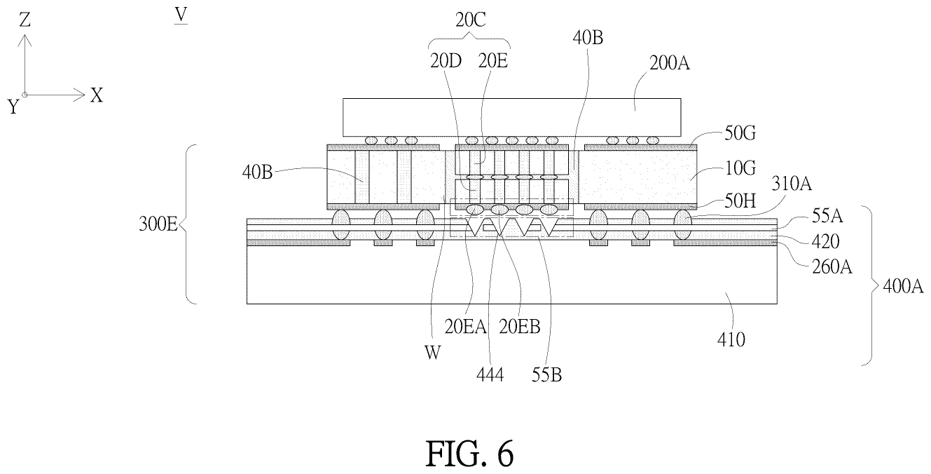

As shown in FIG. 6, the electronic device V includes a board structure 300E, a plurality of electronic components 600 disposed on one side of the board structure 300E, a plurality of external conductive structures 310A disposed on the other side of the board structure 300E, and a substrate 400A electrically connected to the external conductive structures 310A. The board structure 300E includes a bridging board 10G, one or more function chip units 20C, one or more gaps (not labeled) corresponding to the function chip units 20C, one or more filling materials 40B corresponding to the function chip units 20C, and two layer structures 50G, 50H respectively disposed on both sides of the bridging board 10G. Taking the layer structures 50G, 50H as single electrical layers as an example, the function chip units 20C as two function chip units 20D, 20E as an example, and the external conductive structures 310A as copper bumps as an example, a conductive member 70H electrically connects the layer structures 50G, 50H on both sides of the bridging board 10F. The substrate 400A is a multi-layer structure of at least two layers 410, 420, and includes electrical layers 250A corresponding to the external conductive structures 310A, and a waveguide structure 55A corresponding to the function chip units 20C. The function chip unit 20E is an optoelectronic conversion element array, including at least a light-emitting element array 20EA and a photosensitive element array 20EB. The function chip unit 20D is an optoelectronic conversion driving circuit. The electronic component 600 is a semiconductor main chip. The function chip unit 20D electrically connects the function chip unit 20E and the electronic component 600. The waveguide structure 55A can be directly or indirectly connected to the board structure 300E, and defines a light coupling region 55B, correspondingly coupled to the light-emitting element array 20EA and the photosensitive element array 20EB. The optoelectronic conversion element array performs optical signal transmission and reception with the waveguide structure 55A, and is electrically driven by the function chip unit 20D to execute conversion between optical and electrical signals. The light coupling region 55B can be further provided with micro-concave-convex structures 444 to optimize coupling efficiency. In this embodiment, the electronic component 600 defines a vertical direction, and at least a portion of the electronic component 600, at least a portion of the function chip unit 20D, at least a portion of the function chip unit 20E, and at least a portion of the waveguide structure 55A are arranged along the vertical direction of the electronic component 600, or furthermore arranged sequentially along the vertical direction. The implementations in FIG. 3 can be combined with previous implementations, such as horizontal parallel or vertical stacking configurations of different function chip units.

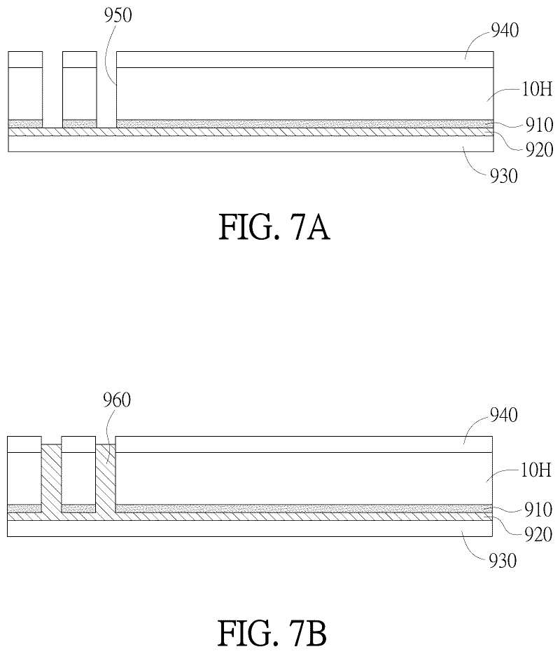

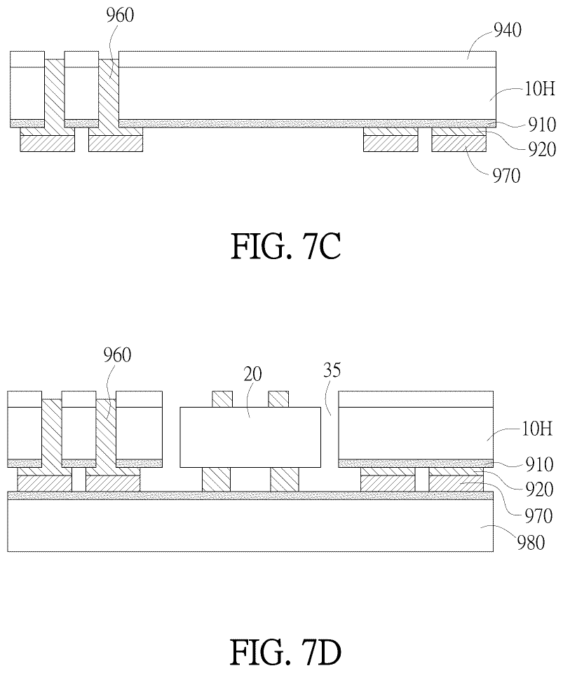

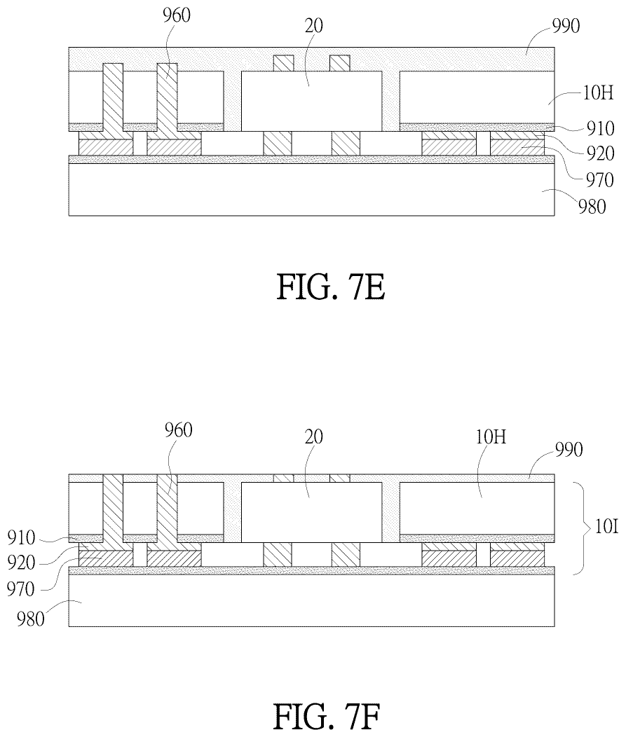

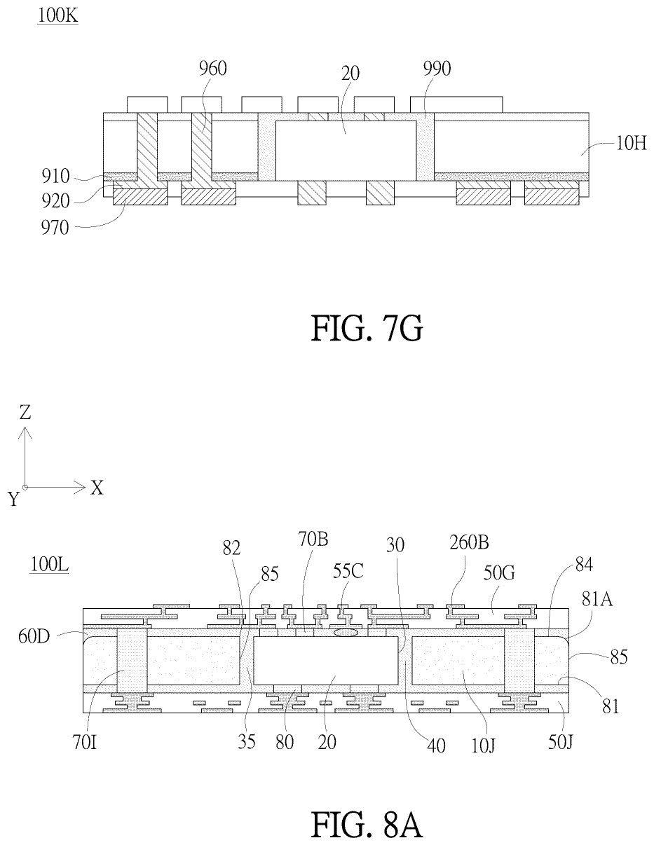

FIGS. 7A to 7G disclose one method of manufacturing the board structure 100K in this document, but are not limited thereto. In FIGS. 7A to 7C, one side of the bridging board 10H is pre-disposed via a bonding sheet 910 on a carrier film 930 having a thin metal film 920, and a sacrificial film 940 is disposed on the other side of the bridging board 10H. Laser drilling is performed from the other side of the bridging board 10H and stops at the thin metal film 920; a seed layer 950 is disposed in the holes, and then electroplating is performed. After conductive members 960 are formed by electroplating to a specific degree, the carrier film 930 is removed, and an electrical layer 970 may be further disposed on the thin metal film 920; in addition, the thin metal film 920 (and the electrical layer 970 thereof) is further subjected to a patterning process. Referring to FIGS. 7D to 7G, at this time, the semi-finished product from which the carrier film 930 has been removed is transferred to a temporary carrier board 980, which may be a rigid board, such as a glass substrate. A channel 35 is formed in the bridging board 10H, and a functional chip unit 20 is disposed in the channel 35; meanwhile, a filling material and a material property layer (collectively referred to as an EMC molding 990, i.e., Epoxy Molding Compound molding, in this embodiment) are completed. Related processes regarding optical/electrical communication may be performed on the functional chip unit 20 before, during, or after the EMC molding process, and a surface of the EMC molding 990 is ground to expose at least a part for electrical communication (e.g., the conductive members 960 and pins 960A of the functional chip unit 20). Finally, the temporary carrier board 980 can be removed to obtain the board structure 100K. It is worth noting that intermediate product structures capable of commercial circulation include at least those shown in FIG. 7G, wherein the bridging board 10H and the temporary carrier board 980 can be regarded as a bridging board intermediate structure.

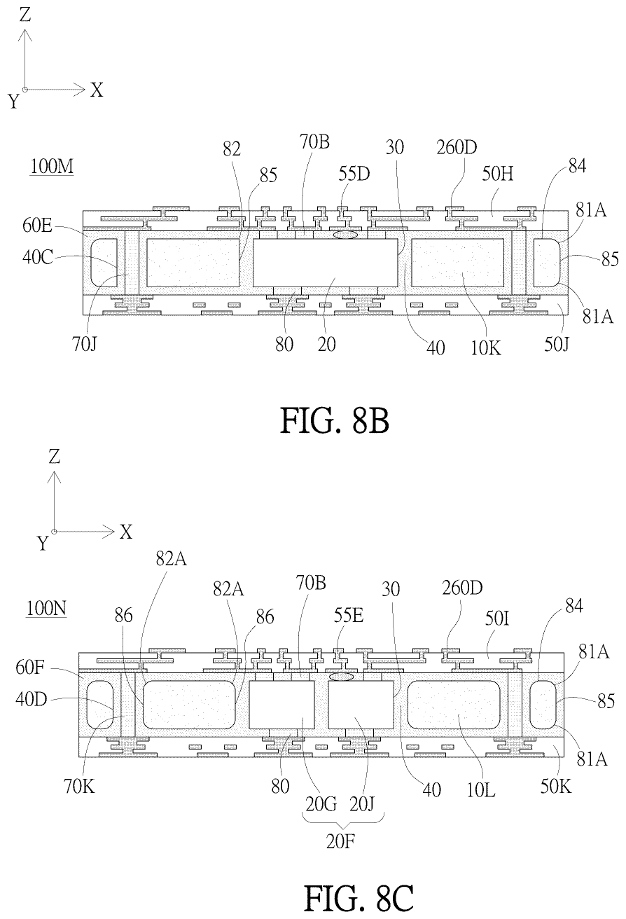

In the board structures 100L, 100M, and 100N shown in FIG. 8A, FIG. 8B, and FIG. 8C, the bridging board defines one or more corners or side edges, and a chamfer is disposed at one of the corners or the side edges. The material property layer is arranged in a planar manner along the plane of the bridging board and wraps the corner or corners, or the side edge or edges, of one or more bridging boards (if the bridging boards are spliced and connected with one another). In the board structure 100L, a bridging board 10J defines one or more outer corners 81, inner corners 82, or outer upper and lower edges 84, outer peripheral edges 85, and inner peripheral edges 86; it can be understood that the inner corners 82 and inner peripheral edges 86 are located at the channel 35. In this embodiment, a chamfer 83 is configured at one of the outer corners (labeled as 81A, to distinguish from the non-chamfered outer corners 81), and the material property layer 60D wraps the chamfer 83. The material property layer 60D may further include at least one of the outer upper and lower edges 84 or the outer peripheral edge 85, in particular the outer peripheral edge 85. The chamfer 83 of the bridging board 10J is arranged only at one outer corner 81A. Specifically, a layer structure 50G includes an electrical layer 260B and an optical layer (waveguide structure) 55C, and the function chip unit 20 has optoelectronic properties; in this embodiment, the chamfer 83 of the bridging board 10J is arranged only at the outer corner 81A relative to the layer structure 50G. In this embodiment, apart from the layer structure 50G, the bridging board 10J may further include a layer structure 50J, with the two layer structures 50G and 50J respectively arranged on opposite sides of the bridging board 10J and exemplified as being asymmetric; for example, the layer structure 50G may be an RDL, while the layer structure 50J may be a build-up layer (such as ABF), but the present disclosure is not limited thereto.

In the board structure 100M, the difference between the bridging board 10K and the bridging board 10J includes that the chamfer 83 of the bridging board 10K is arranged at the opposing two outer corners 81A of the bridging board 10K; the material property layer 60E wraps to the chamfer 83, and the material property layer 60D may further include at least one of the outer upper and lower edges 84 or the outer peripheral edge 85, in particular the outer peripheral edge 85. In addition, in the board structure 100L, a conductive member 70I is independent of the channel and directly penetrates through the bridging board 10J, whereas in the board structure 100M, a conductive member 70J further penetrates through a filling material 40C in the bridging board 10K; in other words, in the board structure 100M, the hole in the bridging board 10K can first be filled with the filling material 40C for the conductive member 70J to pass through, and is electrically connected to the layer structure 50H; the layer structure 50H may likewise include an electrical layer 260C and an optical layer (waveguide structure) 55D, and the function chip unit 20 likewise has optoelectronic properties. Furthermore, in the board structure 100M, the conductive member 70I further penetrates through the material property layer 60N connected to the bridging board 10K.

In the board structure 100N, the difference between the bridging board 10L and the bridging board 10K includes that the chamfer 83 of the bridging board 10L is further configured at an inner corner 82A of the bridging board 10L; the material property layer 60E wraps to the chamfer 83, and the material property layer 60D may further include at least one of the outer upper and lower edges 84 or the outer peripheral edge 85, in particular the outer peripheral edge 85. Wherein, the chamfer 83 can also be further arranged in the hole where a filling material 40D and a conductive member 70K are arranged. Here, the conductive member 70K is independent of the channel, penetrates through the bridging board 10L, the filling material 40D, and its material property layer 60F, and is electrically connected to the layer structure 50I. It is noteworthy that the material property layer and the filling material can be formed simultaneously with the bridging board, and then holes and channels can be formed through the bridging board, the material property layer, and the filling material, after which subsequent processes can be carried out. The material property layer and the filling material can be made of the same or different materials; in addition, as shown in the series of FIG. 5, the material property layer, the filling material, and the protective layer can be made of the same or different materials. Furthermore, the differences between the bridging board 10L and the bridging board 10K further include that a function chip unit 20F comprises a first chip 20G and a second chip 20J; the first chip 20G is electrically connected to the electrical layer 260D of the layer structure 50I, and the second chip 20J is electrically connected to the electrical layer 260D and the waveguide structure 55E of the layer structure 50I.

Based on the above description, it should be understood that various embodiments of the present invention have been described in the specification for illustrative purposes, and various modifications can be made without departing from the scope and spirit of the present invention. Therefore, the various embodiments of the present invention are not intended to limit the true scope and spirit of the invention.

The above descriptions are exemplary rather than restrictive. Any equivalent modifications or changes made without departing from the spirit and scope of this invention should be included in the appended patent claims.

What is claimed is:

1. A substrate architecture, comprising:
a bridging substrate, defining a coefficient of thermal expansion (CTE) no greater than 10 ppm/° C. along a horizontal plane thereof; wherein the bridging substrate has a passage;
a function chip unit at least partially accommodated in the passage;
a gap derived between the function chip unit and the bridging substrate; and
a filling material arranged in the gap.

2. The substrate architecture of claim 1, wherein the bridging substrate includes glass, Silica (silicon dioxide, SiO₂), ceramic, glass-ceramic, compound semiconductor material, or polyimide, or a combination of one or more of the above materials.

3. The substrate architecture of claim 1, wherein the coefficient of thermal expansion of the bridging substrate is no greater than 10 ppm/° C. along the horizontal plane.

4. The substrate architecture of claim 1, wherein the function chip unit defines a coefficient of thermal expansion (CTE) along the horizontal plane; a ratio of the CTE of the bridging substrate to the CTE of the function chip unit is no less than 0.5, or/and not greater than 2.5.

5. The substrate architecture of claim 1, wherein the filling material defines a coefficient of thermal expansion (CTE) along the horizontal plane; the CTE of the filling material is greater than both the CTE of the bridging substrate and the CTE of the function chip unit.

6. The substrate architecture of claim 1, wherein the functional chip unit includes one or more bridge dies (BD), deep trench capacitors (DTC), voltage regulators (VR), integrated passive devices (IPD), EIC (Electrical Integrated Circuit), PIC (Photonic Integrated Circuit) or optoelectronic elements, or a combination of one or more of the above components.

7. The substrate architecture of claim 1, further including a material property layer arranged at a side of the bridging structure, at least partially covering the gap, and connecting the filling material.

8. The substrate architecture of claim 7, wherein the material property layer defines a coefficient of thermal expansion (CTE) along the horizontal plane, and a difference between the coefficient of thermal expansion of the material property layer and the coefficient of thermal expansion of the bridging substrate does not exceed 1.3 ppm/° C., or/and not less than 0.7 ppm/° C.

9. The substrate architecture of claim 1, wherein the further including a conductive member arranged through the bridging substrate and individual from the passage.

10. The substrate architecture of claim 1, further including a layer structure at least partially covering one of the two sides of the bridging substrate, the gap, and the bridging chip unit; wherein the layer structure is in communication with the bridging chip unit by at least one type of electrical signals and optical signals.

11. The substrate architecture of claim 10, wherein the layer structure defines a dielectric loss (Df) of no greater than 0.006 at a frequency of 10 GHz.

12. The substrate architecture of claim 11, further including an opposite layer structure at least partially covers an opposite side of the bridging substrate, the gap, and the function chip unit and counter to the layer structure; the opposite layer structure communicates with the function chip unit by at least one type of electrical signals and optical signals.

13. The substrate architecture of claim 12, wherein an absolute difference ratio of the total volume expansion within a plane range of the bridging substrate between the layer structure and the opposite layer structure is not less than 30%.

14. The substrate architecture of claim 10, wherein the function chip unit defines a line width no greater than 1 μm on a side thereof facing the layer structure.

15. The substrate architecture of claim 7, wherein the bridging substrate defines one or more corners or edges; the material property layer is arranged in a planar manner along the horizontal plane of the bridging substrate, and the material property layer wraps at least one of the edges.

16. The substrate architecture of claim 7, wherein the bridging substrate defines one or more corners or edges, and a chamfer disposed at one of the corners or edges; the material property layer is arranged in a planar manner along the horizontal plane of the bridging substrate, and the material property layer wraps the chamfer

17. A stacked substrate architecture, comprising:
a packaged substrate; and
a substrate architecture as claimed in claim 1, stacked on the packaged substrate; wherein the functional chip unit of the substrate architecture communicates with the packaged substrate through at least one of electrical signals and optical signals.

18. The stacked substrate architecture of claim 17, wherein the packaged substrate comprises glass, Silica (silicon dioxide, SiO₂), ceramic, glass-ceramic, compound semiconductor material, polyimide, BT, FR4, or a combination of one or more of the above materials.

19. An electronic device, comprising:
a substrate;
a substrate architecture as claimed in claim 1, stacked to the substrate;
a plurality of electronic components, arranged at a side of the substrate architecture in communication with the function chip unit through the layer structure, wherein the communication includes at least one type of electrical signals and optical signals; and
a plurality of external conductive components, arranged at an opposite side of the substrate architecture, wherein the external conductive components are arranged between and electrically connected with the substrate architecture and the substrate.

20. The electronic device of claim 19, wherein one of the electronic components includes a HBM (High Bandwidth Memory), or a Switch, or a NPU (Neural Processing Unit), TPU (Tensor Processing Unit), CPU (Central Processing Unit), or a GPU (Graphics Processing Unit), or any combination containing any component thereof.
